(19) United States
(12) Patent Application Publication
(10) Pub. No.: US 2026/0255945 A1
(43) Pub. Date: Aug. 27, 2026

(54) DESIGN METHOD OF SEMICONDUCTOR STRUCTURE

(71) Applicant: Powerchip Semiconductor Manufacturing Corporation, Hsinchu (TW)

(72) Inventor: Jhih-Siang Yang, Hsinchu (TW)

(73) Assignee: Powerchip Semiconductor Manufacturing Corporation, Hsinchu (TW)

(21) Appl. No.: 19/214,005

(22) Filed: May 20, 2025

(30) Foreign Application Priority Data
Feb. 26, 2025 (TW) 114107083

(51) Int. Cl. H01L 23/522; G06F 30/3953

(52) U.S. Cl. CPC H10W 20/42; G06F 30/3953

(57) ABSTRACT

A semiconductor structure includes n conductive layers and a via. The n conductive layers are separated from each other. There is an opening in the semiconductor structure. The via is located in the opening. The opening penetrates through n conductive layers to form n holes in n conductive layers. The via and top surfaces of n−1 conductive layers have n−1 annular overlapping regions. n is an integer greater than 1. A design method of the semiconductor structure can calculate a width of an (n−1)th annular overlapping region and an nth minimum diameter at a top of an nth hole. Therefore, the width of the (n−1)th annular overlapping region and the nth minimum diameter at the top of the nth hole can be adjusted according to needs, thereby the interface resistance between the conductive layer and the via and the size of the hole in the conductive layer can be optimized.

### CROSS-REFERENCE TO RELATED APPLICATION

This application claims the priority benefit of Taiwan application serial no. 114107083, filed on Feb. 26, 2025. The entirety of the above-mentioned patent application is hereby incorporated by reference herein and made a part of this specification.

### BACKGROUND

### Technical Field

The disclosure relates to a design method of a semiconductor structure, and particularly relates to a design method of semiconductor structure including a via.

### Related Art

Currently, in some semiconductor structures, multiple metal layers are electrically connected through vias penetrating through multiple conductive layers. In the manufacturing process of the vias, openings for accommodating the vias are formed, and the openings penetrate through multiple conductive layers to form multiple holes in the multiple conductive layers. However, how to optimize the interface resistance between the conductive layers and the vias and the size of the holes in the conductive layers remains an ongoing goal.

### SUMMARY

The disclosure provides a design method of a semiconductor structure, which can optimize an interface resistance between a conductive layer and a via and a size of a hole in the conductive layer.

The disclosure proposes a design method of a semiconductor structure. The semiconductor structure includes n conductive layers and a via. The n conductive layers are separated from each other. There is an opening in the semiconductor structure. The via is located in the opening. The opening penetrates through the n conductive layers to form n holes in the n conductive layers. The via and top surfaces of n−1 conductive layers have n−1 annular overlapping regions. n is an integer greater than 1. The design method of the semiconductor structure includes steps as follows. An (n−1)th minimum diameter at a top of an (n−1)th hole is provided. A distance between a bottom of an (n−1)th conductive layer and a bottom of an nth conductive layer, an interface resistance between the (n−1)th conductive layer and the via, an included angle between a top surface of the (n−1)th conductive layer and a sidewall of the via, and a thickness of the (n−1)th conductive layer are defined. A side resistance between a sidewall of an (n−1)th conductive layer exposed by the (n−1)th hole and the via are calculated. An overlap resistance of an (n−1)th annular overlapping region is calculated. A width of the (n−1)th annular overlapping region is calculated based on the (n−1)th minimum diameter, the thickness, the side resistance, and the overlap resistance. An nth minimum diameter at a top of an nth hole is calculated based on the included angle, the (n−1)th minimum diameter, the width, and the distance.

According to an embodiment of the disclosure, in the design method of the semiconductor structure, in response to n being 2, a method of providing the (n−1)th minimum diameter may include calculating the (n−1)th minimum diameter based on an etch margin.

According to an embodiment of the disclosure, in the design method of the semiconductor structure, a method of calculating the side resistance may include calculating the side resistance based on the (n−1)th minimum diameter and the thickness.

According to an embodiment of the disclosure, in the design method of the semiconductor structure, a method of calculating the overlap resistance may include calculating the overlap resistance based on the interface resistance and the side resistance.

According to an embodiment of the disclosure, in the design method of the semiconductor structure, the width may be calculated by Formula 1 as follows.

$${W}_{n - 1} = \sqrt{( {( \frac{{h}_{n - 1}}{2} )}^{2} + {h}_{n - 1} \times {T}_{n - 1} \times \frac{{RS}_{n - 1}}{{RO}_{n - 1}} )} - \frac{{h}_{n - 1}}{2} \qquad Formula 1$$

In the formula, Wₙ₋₁ is the width of the (n−1)th annular overlapping region, hₙ₋₁ is the (n−1)th minimum diameter at the top of the (n−1)th hole, Tₙ₋₁ is the thickness of the (n−1)th conductive layer, RSₙ₋₁ is the side resistance between the sidewall of the (n−1)th conductive layer exposed by the (n−1)th hole and the via, and ROₙ₋₁ is the overlap resistance of the (n−1)th annular overlapping region.

According to an embodiment of the disclosure, in the design method of the semiconductor structure, the nth minimum diameter may be calculated by Formula 2 as follows.

$$180 ° - {θ}_{n - 1} = {tan}^{- 1} [ \frac{{h}_{n} - {h}_{n - 1} - {W}_{n - 1} \times 2}{2 \times {H}_{n - 1}} ] \qquad Formula 2$$

In the formula, hₙ is the nth minimum diameter at the top of the nth hole, hₙ₋₁ is the (n−1)th minimum diameter at the top of the (n−1)th hole, θₙ₋₁ is the included angle between the top surface of the (n−1)th conductive layer and the sidewall of the via, Wₙ₋₁ is the width of the (n−1)th annular overlapping region, and Hₙ₋₁ is the distance between the bottom of the (n−1)th conductive layer and the bottom of the nth conductive layer.

According to an embodiment of the disclosure, in the design method of the semiconductor structure, the semiconductor structure further includes a first wiring layer. A bottom of the via is connected to the first wiring layer.

According to an embodiment of the disclosure, in the design method of the semiconductor structure, the semiconductor structure further includes a second wiring layer. A top of the via is connected to the second wiring layer.

According to an embodiment of the disclosure, in the design method of the semiconductor structure, the n conductive layers may be multiple metal layers.

According to an embodiment of the disclosure, in the design method of the semiconductor structure, the material of the via is, for example, metal.

Based on the above, in the design method of the semiconductor structure proposed by the disclosure, the width of the (n−1)th annular overlapping region and the nth minimum diameter at the top of the nth hole can be calculated. Therefore, the width of the (n−1)th annular overlapping region and the nth minimum diameter at the top of the nth hole can be adjusted according to needs, thereby the interface resistance between the conductive layer and the via and the size of the hole in the conductive layer can be optimized.

To make the foregoing features and advantages of the disclosure more comprehensible, embodiments are provided below with detailed descriptions together with the accompanying drawings.

### BRIEF DESCRIPTION OF THE DRAWINGS

FIG. 1 is a cross-sectional view of a semiconductor structure according to some embodiments of the disclosure.

FIG. 2 is a perspective view of a region RR in FIG. 1.

FIG. 3 is a flowchart of a design method of a semiconductor structure according to some embodiments of the disclosure.

### DESCRIPTION OF THE EMBODIMENTS

The following embodiments are described in detail with reference to the accompanying drawings, but the provided embodiments are not intended to limit the scope covered by the disclosure. For ease of understanding, the same components in the following description will be marked with the same reference numerals. In addition, the accompanying drawings are merely for illustration purposes and are not drawn according to the original dimensions. Furthermore, the features in the cross-sectional view and the features in the perspective view are not drawn to the same scale. In fact, for clarity of discussion, the dimensions of various features may be arbitrarily enlarged or reduced.

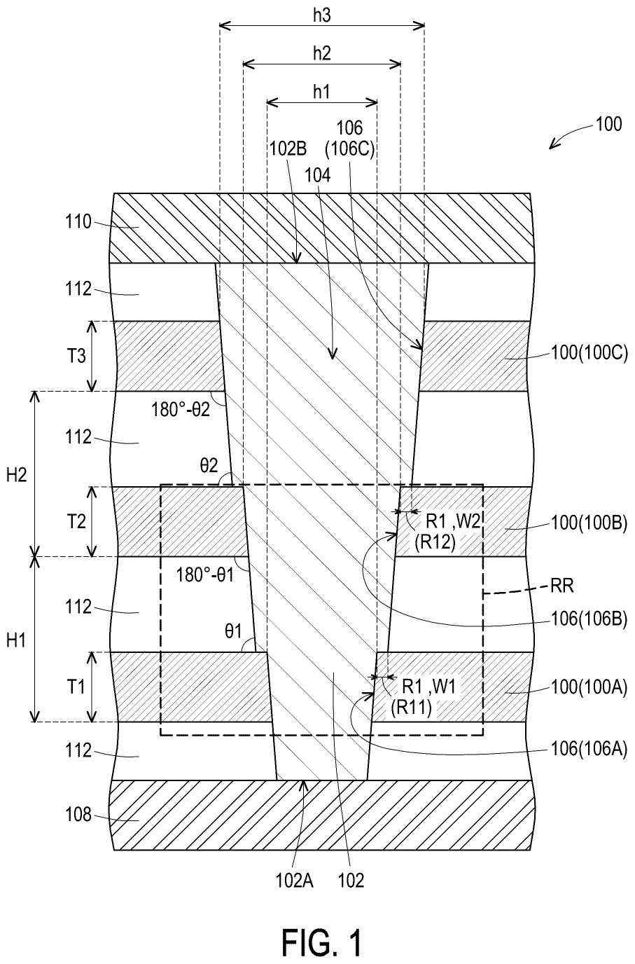

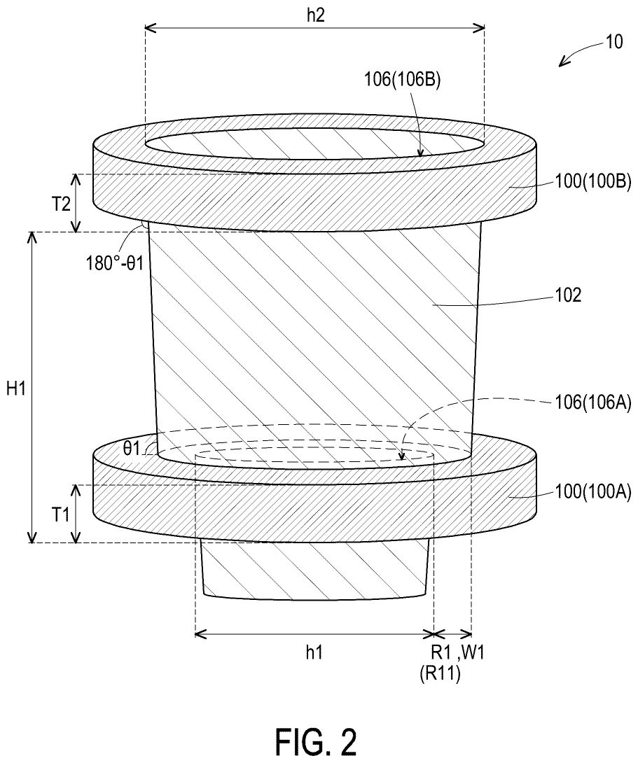

FIG. 1 is a cross-sectional view of a semiconductor structure according to some embodiments of the disclosure. FIG. 2 is a perspective view of a region RR in FIG. 1. In FIG. 2, some components in FIG. 1 are omitted to clearly illustrate the arrangement relationship between the components in FIG. 2.

A design method of a semiconductor structure of this embodiment may be adapted to a semiconductor structure 10 as shown in FIG. 1 and FIG. 2. Referring to FIG. 1 and FIG. 2, the semiconductor structure 10 includes n conductive layers 100 and a via 102. The n conductive layers 100 are separated from each other. There is an opening 104 in the semiconductor structure 10. The via 102 is located in the opening 104. The opening 104 penetrates through the n conductive layers 100 to form n holes 106 in the n conductive layers 100. The via 102 and top surface of n−1 conductive layers 100 have n−1 annular overlapping regions R1. n is an integer greater than 1. In some embodiments, the n conductive layers 100 may be multiple metal layers. In some embodiments, the material of the via 102 is, for example, metal. In addition, although not shown in the drawings, the n conductive layers 100 may be located on a substrate structure, while the description of which is omitted here. Furthermore, the quantity of the conductive layers 100 and the quantity of the holes 106 are not limited to the quantity shown in the drawings. As long as the quantity of the conductive layers 100 and the quantity of the holes 106 are multiple, they fall within the scope covered by the disclosure.

In some embodiments, the semiconductor structure 10 may further include a wiring layer 108. A bottom 102A of the via 102 is connected to the wiring layer 108. In some embodiments, the semiconductor structure 10 may further include a wiring layer 110. A top 102B of the via 102 is connected to the wiring layer 110. In some embodiments, the wiring layer 108 and the wiring layer 110 may be interconnect structures or redistribution layers (RDL).

In some embodiments, the n conductive layers 100 may be conductive layers on different wafers or conductive layers on the same wafer. In some embodiments, the semiconductor structure 10 may further include multiple intermediate structures 112. The multiple intermediate structures 112 are located between the multiple conductive layers 100, between the conductive layer 100 and the wiring layer 108, and between the conductive layer 100 and the wiring layer 110. In some embodiments, the intermediate structure 112 may include a dielectric layer, an interconnect structure, a semiconductor component, a semiconductor substrate, or a combination thereof.

In this embodiment, n is exemplified as 3 for explanation, but the disclosure is not limited thereto. For example, when n is 3, the n conductive layers 100 may include a conductive layer 100A, a conductive layer 100B, and a conductive layer 100C, the n holes 106 may include a hole 106A, a hole 106B, and a hole 106C, and the n−1 annular overlapping regions R1 may include an annular overlapping region R11 and an annular overlapping region R12.

The conductive layer 100A may have a thickness T1. The conductive layer 100B may have a thickness T2. The conductive layer 100C may have a thickness T3. The top of the hole 106A may have a minimum diameter h1. The top of the hole 106B may have a minimum diameter h2. The top of the hole 106C may have a minimum diameter h3. The distance between the bottom of the conductive layer 100A and the bottom of the conductive layer 100B is H1. The distance between the bottom of the conductive layer 100B and the bottom of the conductive layer 100C is H2. There is the annular overlapping region R11 at the via 102 and the top surface of the conductive layer 100A. The width of the annular overlapping region R11 is W1. There is the annular overlapping region R12 at the via 102 and the top surface of the conductive layer 100B. The width of the annular overlapping region R12 is W2. An included angle between the top surface of the conductive layer 100A and the sidewall of the via 102 is θ1. An included angle between the top surface of the conductive layer 100B and the sidewall of the via 102 is θ2.

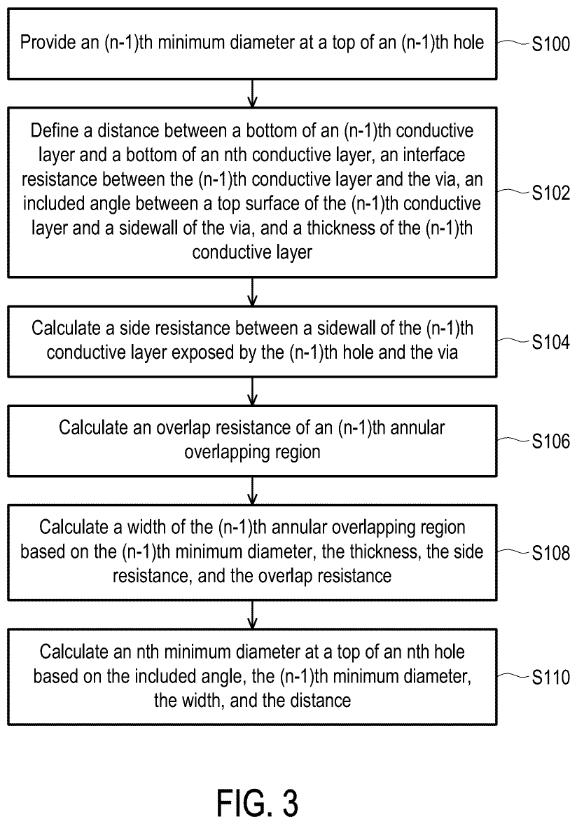

FIG. 3 is a flowchart of the design method of the semiconductor structure according to some embodiments of the disclosure. In the following, the design method of the semiconductor structure according to some embodiments of the disclosure will be described with reference to FIG. 1 to FIG. 3.

Referring to FIG. 1 to FIG. 3, Step S100 is performed to provide an (n−1)th minimum diameter at a top of an (n−1)th hole. In some embodiments, in response to n being 2, a method of providing the (n−1)th minimum diameter may include calculating the (n−1)th minimum diameter based on an etch margin. For example, in FIG. 1 and FIG. 2, the minimum diameter h1 at the top of the hole 106A, a first hole, may be calculated based on an etch margin.

Step S102 is performed to define a distance between a bottom of an (n−1)th conductive layer and a bottom of an nth conductive layer, an interface resistance between the (n−1)th conductive layer and the via, an included angle between a top surface of the (n−1)th conductive layer and a sidewall of the via, and a thickness of the (n−1)th conductive layer. That is, the distance between the bottom of the (n−1)th conductive layer and the bottom of the nth conductive layer, the interface resistance between the (n−1)th conductive layer and the via, the included angle between the top surface of the (n−1)th conductive layer and the sidewall of the via, and the thickness of the (n−1)th conductive layer are known parameters. For example, in FIG. 1 and FIG. 2, the distance H1, the interface resistance between the conductive layer 100A and the via 102, the included angle θ1, and the thickness T1 are known parameters.

Step S104 is performed to calculate a side resistance between a sidewall of the (n−1)th conductive layer exposed by the (n−1)th hole and the via. In some embodiments, a method of calculating the side resistance may include calculating the side resistance based on the (n−1)th minimum diameter and the thickness. For example, in FIG. 1 and FIG. 2, the side resistance between the sidewall of the conductive layer 100A exposed by the hole 106A and the via 102 may be calculated based on the minimum diameter h1 and the thickness T1.

Step S106 is performed to calculate an overlap resistance of an (n−1)th annular overlapping region. In some embodiments, since the interface resistance is the parallel resistance of the side resistance and the overlap resistance, a method of calculating the overlap resistance may include calculating the overlap resistance based on the interface resistance and the side resistance. For example, in FIG. 1 and FIG. 2, the overlap resistance of the annular overlapping region R11 may be calculated based on the interface resistance between the conductive layer 100A and the via 102 and the side resistance between the sidewall of the conductive layer 100A exposed by the hole 106A and the via 102.

Step S108 is performed to calculate a width of the (n−1)th annular overlapping region based on the (n−1)th minimum diameter, the thickness, the side resistance, and the overlap resistance. In some embodiments, the width may be calculated by Formula 1 as follows.

$${W}_{n - 1} = \sqrt{( {( \frac{{h}_{n - 1}}{2} )}^{2} + {h}_{n - 1} \times {T}_{n - 1} \times \frac{{RS}_{n - 1}}{{RO}_{n - 1}} )} - \frac{{h}_{n - 1}}{2} \qquad Formula 1$$

In the formula, Wₙ₋₁ is the width of the (n−1)th annular overlapping region, hₙ₋₁ is the (n−1)th minimum diameter at the top of the (n−1)th hole, Tₙ₋₁ is the thickness of the (n−1)th conductive layer, RSₙ₋₁ is the side resistance between the sidewall of the (n−1)th conductive layer exposed by the (n−1)th hole and the via, and ROₙ₋₁ is the overlap resistance of the (n−1)th annular overlapping region. For example, in FIG. 1 and FIG. 2, the width W1 of the annular overlapping region R11 may be calculated based on the minimum diameter h1, the thickness T1, the side resistance between the sidewall of the conductive layer 100A exposed by the hole 106A and the via 102, and the overlap resistance of the annular overlapping region R11.

Step S110 is performed to calculate an nth minimum diameter at a top of a nth hole based on the included angle, the (n−1)th minimum diameter, the width, and the distance. In some embodiments, the nth minimum diameter may be calculated by Formula 2 as follows.

$$180 ° - {θ}_{n - 1} = {tan}^{- 1} [ \frac{{h}_{n} - {h}_{n - 1} - {W}_{n - 1} \times 2}{2 \times {H}_{n - 1}} ] \qquad Formula 2$$

In the formula, hₙ is the nth minimum diameter at the top of the nth hole, hₙ₋₁ is the (n−1)th minimum diameter at the top of the (n−1)th hole, θₙ₋₁ is the included angle between the top surface of the (n−1)th conductive layer and the sidewall of the via, Wₙ₋₁ is the width of the (n−1)th annular overlapping region, and Hₙ₋₁ is the distance between the bottom of the (n−1)th conductive layer and the bottom of the nth conductive layer. For example, in FIG. 1 and FIG. 2, the minimum diameter h2 at the top of the hole 106B may be calculated based on the minimum diameter h1, the included angle θ1, the width W1, and the distance H1.

In some embodiments, after calculating the width W1 and the minimum diameter h2, Steps S102, S104, S106, S108, and S110 may be repeated to calculate the width W2 of the annular overlapping region R12 and the minimum diameter h3 at the top of the hole 106C. In this embodiment, the via 102 and the top surface of the conductive layer 100C do not have an annular overlapping region, but the disclosure is not limited thereto. In other embodiments, the via 102 and the top surface of the conductive layer 100C may have an annular overlapping region (not shown).

Based on the above embodiments, it is known that in the design method of the semiconductor structure, the width of the (n−1)th annular overlapping region and the nth minimum diameter at the top of the nth hole can be calculated. Therefore, the width of the (n−1)th annular overlapping region and the nth minimum diameter at the top of the nth hole can be adjusted according to needs, thereby the interface resistance between the conductive layer and the via and the size of the hole in the conductive layer can be optimized. For example, in FIG. 1 and FIG. 2, by the design method of the semiconductor structure of the foregoing embodiments, the interface resistance between the conductive layer 100A and the via 102 and the minimum diameter h2 at the top of the hole 106B in the conductive layer 100B can be optimized.

In summary, by the design method of the semiconductor structure of the foregoing embodiments, the width of the (n−1)th annular overlapping region and the nth minimum diameter at the top of the nth hole can be adjusted according to needs, thereby the interface resistance between the conductive layer and the via and the size of the hole in the conductive layer can be optimized.

Although the disclosure has been disclosed in the embodiments, the embodiments are not intended to limit the disclosure. Persons with ordinary knowledge in the relevant technical field may make some changes and modifications without departing from the spirit and scope of the disclosure. Therefore, the scope of protection of the disclosure shall be defined by the appended claims.

What is claimed is:

1. A design method of a semiconductor structure, wherein the semiconductor structure comprises n conductive layers and a via, the n conductive layers are separated from each other, there is an opening in the semiconductor structure, the via is located in the opening, the opening penetrates through the n conductive layers to form n holes in the n conductive layers, the via and top surfaces of n−1 conductive layers have n−1 annular overlapping regions, n is an integer greater than 1, and the design method of the semiconductor structure comprises:
providing an (n−1)th minimum diameter at a top of an (n−1)th hole;
defining a distance between a bottom of an (n−1)th conductive layer and a bottom of an nth conductive layer, an interface resistance between the (n−1)th conductive layer and the via, an included angle between a top surface of the (n−1)th conductive layer and a sidewall of the via, and a thickness of the (n−1)th conductive layer;
calculating a side resistance between a sidewall of the (n−1)th conductive layer exposed by the (n−1)th hole and the via;
calculating an overlap resistance of an (n−1)th annular overlapping region;
calculating a width of the (n−1)th annular overlapping region based on the (n−1)th minimum diameter, the thickness, the side resistance, and the overlap resistance; and
calculating an nth minimum diameter at a top of an nth hole based on the included angle, the (n−1)th minimum diameter, the width, and the distance.

2. The design method of the semiconductor structure according to claim 1, wherein
in response to n being 2, a method of providing the (n−1)th minimum diameter comprises calculating the (n−1)th minimum diameter based on an etch margin.

3. The design method of the semiconductor structure according to claim 1, wherein a method of calculating the side resistance comprises calculating the side resistance based on the (n−1)th minimum diameter and the thickness.

4. The design method of the semiconductor structure according to claim 1, wherein a method of calculating the overlap resistance comprises calculating the overlap resistance based on the interface resistance and the side resistance.

5. The design method of the semiconductor structure according to claim 1, wherein the width is calculated by Formula 1 as follows,
$${W}_{n - 1} = \sqrt{( {( \frac{{h}_{n - 1}}{2} )}^{2} + {h}_{n - 1} \times {T}_{n - 1} \times \frac{{RS}_{n - 1}}{{RO}_{n - 1}} )} - \frac{{h}_{n - 1}}{2} \qquad Formula 1$$
wherein Wₙ₋₁ is the width of the (n−1)th annular overlapping region,
hₙ₋₁ is the (n−1)th minimum diameter at the top of the (n−1)th hole,
Tₙ₋₁ is the thickness of the (n−1)th conductive layer,
RSₙ₋₁ is the side resistance between the sidewall of the (n−1)th conductive layer exposed by the (n−1)th hole and the via, and
ROₙ₋₁ is the overlap resistance of the (n−1)th annular overlapping region.

6. The design method of the semiconductor structure according to claim 1, wherein the nth minimum diameter is calculated by Formula 2 as follows,
$$180 ° - {θ}_{n - 1} = {tan}^{- 1} [ \frac{{h}_{n} - {h}_{n - 1} - {W}_{n - 1} \times 2}{2 \times {H}_{n - 1}} ] \qquad Formula 2$$
wherein hₙ is the nth minimum diameter at the top of the nth hole,
hₙ₋₁ is the (n−1)th minimum diameter at the top of the (n−1)th hole,
θₙ₋₁ is the included angle between the top surface of the (n−1)th conductive layer and the sidewall of the via,
Wₙ₋₁ is the width of the (n−1)th annular overlapping region, and
Hₙ₋₁ is the distance between the bottom of the (n−1)th conductive layer and the bottom of the nth conductive layer.

7. The design method of the semiconductor structure according to claim 1, wherein the semiconductor structure further comprises:
a first wiring layer, wherein a bottom of the via is connected to the first wiring layer.

8. The design method of the semiconductor structure according to claim 7, wherein the semiconductor structure further comprises:
a second wiring layer, wherein a top of the via is connected to the second wiring layer.

9. The design method of the semiconductor structure according to claim 1, wherein the n conductive layers comprise a plurality of metal layers.

10. The design method of the semiconductor structure according to claim 1, wherein a material of the via comprises metal.
